(19) United States
(12) Patent Application Publication
(10) Pub. No.: US 2026/0075720 A1
(43) Pub. Date: Mar. 12, 2026

(54) MANUFACTURING METHOD OF CIRCUIT BOARD

(71) Applicant: Unimicron Technology Corp., Taoyuan City (TW)

(72) Inventors: WenHao Chen, Taoyuan City (TW); Cho-Ying Wu, Taoyuan City (TW)

(73) Assignee: Unimicron Technology Corp., Taoyuan City (TW)

(21) Appl. No.: 18/915,347

(22) Filed: Oct. 14, 2024

(30) Foreign Application Priority Data
Sep. 11, 2024 (TW) 113134328

(51) Int. Cl. H05K 3/04

(52) U.S. Cl. CPC H05K 3/046; H05K 2203/0502

(57) ABSTRACT

Disclosed is a manufacturing method of a circuit board including the following steps: providing a substrate with a conductive layer; using a jig to imprint-etch the conductive layer of the substrate to form an intermediate with a concave and convex pattern; and etching the intermediate to form a circuit board with a circuit pattern, wherein the circuit pattern corresponds to a convex portion of the concave and convex pattern.

### CROSS-REFERENCE TO RELATED APPLICATION

This application claims the priority benefit of Taiwan application serial no. 113134328, filed on Sep. 11, 2024. The entirety of the above-mentioned patent application is hereby incorporated by reference herein and made a part of this specification.

### BACKGROUND

### Technical Field

The present disclosure relates to a method of manufacturing a circuit board, and in particular, to a method of manufacturing a circuit board by imprint-etching.

### Description of Related Art

The primary techniques for circuit board manufacturing predominantly encompass subtractive process, full additive process (FAP), and modified semi-additive process (mSAP). These processes invariably incorporate corresponding lithographic procedures. In light of the progressive enhancement of circuit grades, the lithography process requisite for circuit board fabrication, along with its critical equipment (such as aligners, involving stepper type or scanner type), is increasingly subject to strain, potentially resulting in diminished manufacturing efficiency. Consequently, the augmentation of circuit board production efficiency has emerged as a salient research topic.

### SUMMARY

The present disclosure provides a method for manufacturing a circuit board, which may efficiently manufacture the circuit board.

In the disclosure, a manufacturing method of a circuit board includes: providing a substrate with a conductive layer; using a jig to imprint-etch the conductive layer of the substrate to form an intermediate with a concave and convex pattern; and etching the intermediate to form a circuit board with a circuit pattern, wherein the circuit pattern corresponds to a convex portion of the concave and convex pattern.

Based on the above, in the manufacturing method of circuit board, the conductive layer of the substrate is imprint-etched by a jig, thereby making the manufacturing method of circuit board more efficient.

### BRIEF DESCRIPTION OF THE DRAWINGS

FIG. 1A, FIG. 2A, FIG. 3A, FIG. 4, FIG. 5A, and FIG. 6A are partial perspective views of a manufacturing method of a circuit board according to an embodiment of the present disclosure.

FIG. 1B, FIG. 2B, FIG. 3B, FIG. 5B, FIG. 6B, and FIG. 7 are partial cross-sectional schematic views of a manufacturing method of a circuit board according to an embodiment of the present disclosure.

### DESCRIPTION OF THE EMBODIMENTS

The implementation examples enumerated below are described in detail in conjunction with the accompanying drawings. However, the provided implementation examples are not intended to limit the scope of the present disclosure. Furthermore, the drawings are for illustrative purposes only and are not drawn to scale. For instance, for the sake of clarity, the thickness of conductive layers may be exaggerated in all drawings. Similarly, for the purpose of clarity, the dimensions of conductive through-holes 259 and/or their corresponding conductive vias 250 (as indicated in FIG. 3B or subsequent figures) may be exaggerated in FIG. 2A, FIG. 2B, or other similar figures.

In addition, the terms “including”, “having”, etc. used in the description are all open terms, which means “including but not limited to”.

It should be understood that, although the terms “first,” “second,” “third,” and so forth may be used herein to describe various elements, components, regions, layers, and/or segments, these elements, components, regions, layers, and/or segments should not be limited by these terms. These terms are only used to distinguish one element, component, region, layer, or segment from another element, component, region, layer, or segment. Thus, a “first element,” “component,” “region,” “layer,” or “segment” discussed below could be termed a second element, component, region, layer, or segment without departing from the teachings of the present disclosure.

The direction terms mentioned in this description, such as “up”, “down”, etc., are only for reference to the directions of the accompanying drawings. Accordingly, the directional terms used are illustrative and not limiting of the disclosure.

In the following embodiments, the same or similar elements will be denoted by the same or similar numbers, and repeated description thereof will be omitted. In addition, features in different embodiments can be combined with each other without conflict, and simple equivalent changes, modifications or omissions made in accordance with this specification or the scope of the present disclosure are still within the scope of the disclosure.

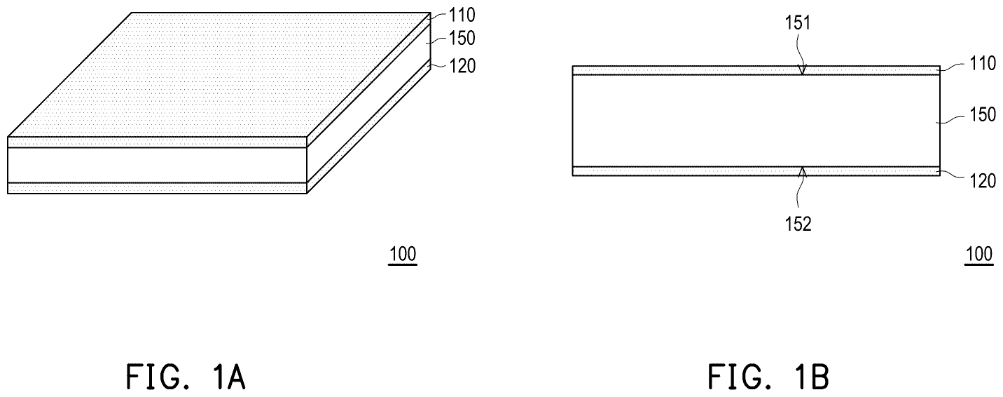

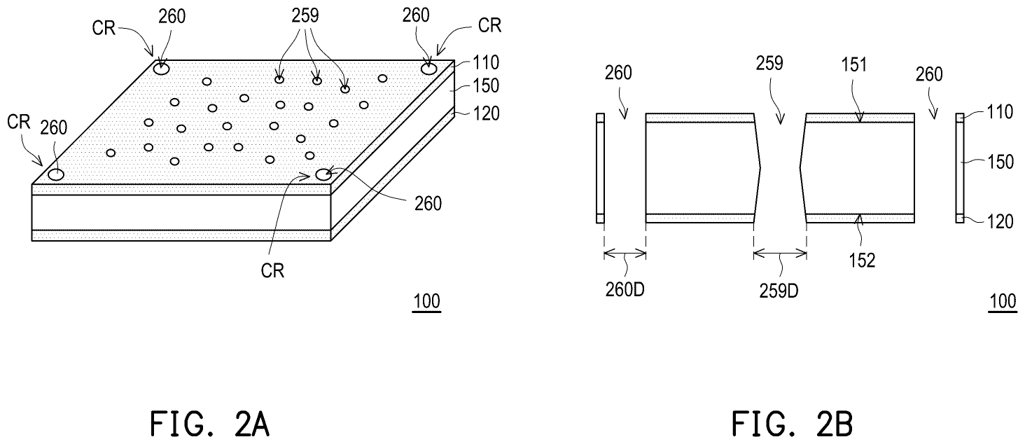

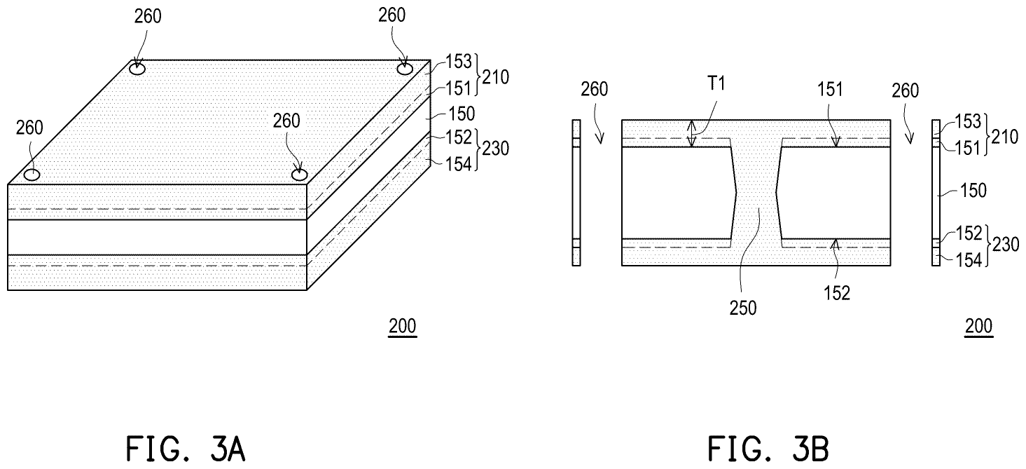

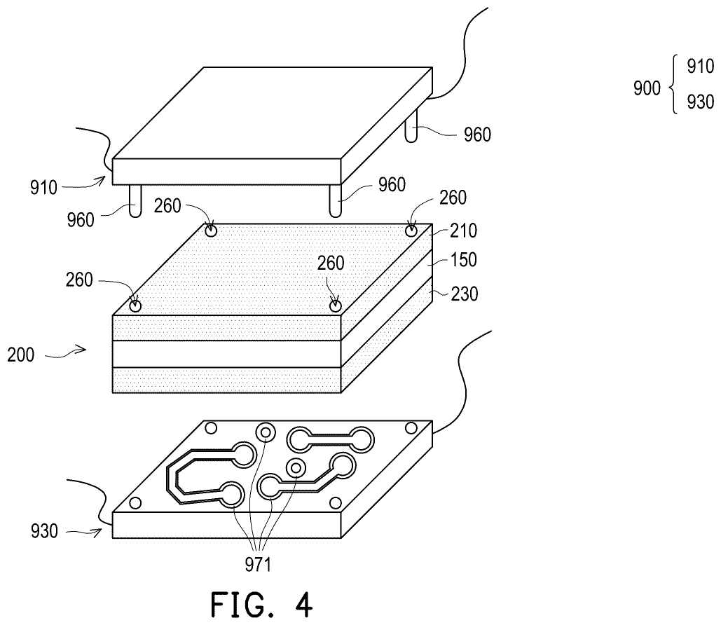

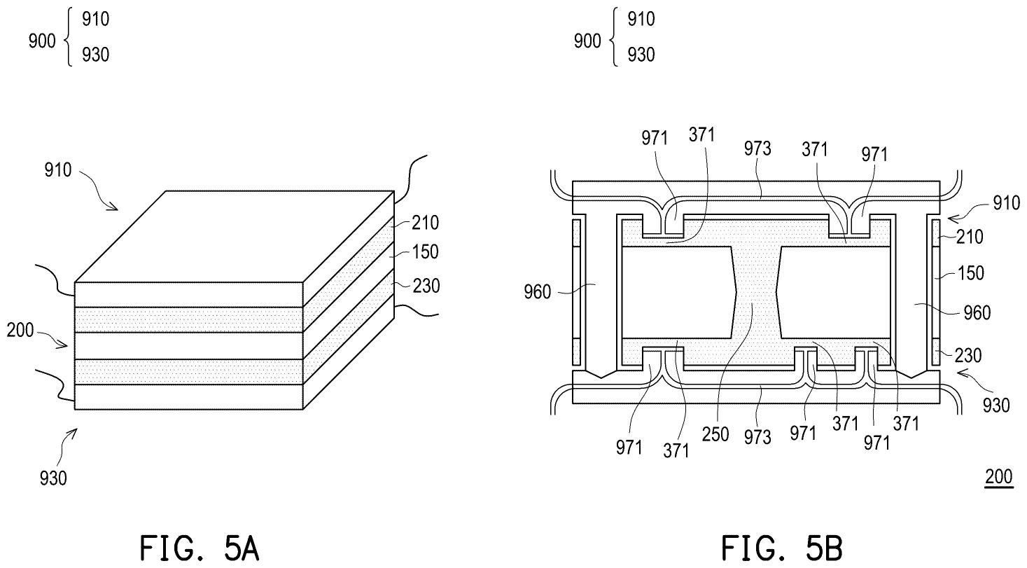

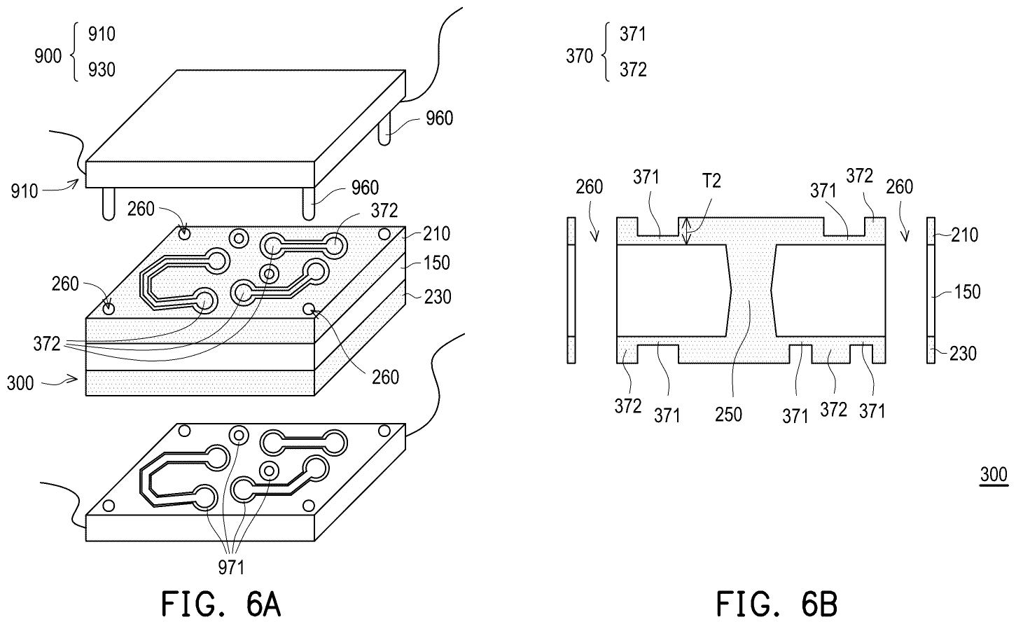

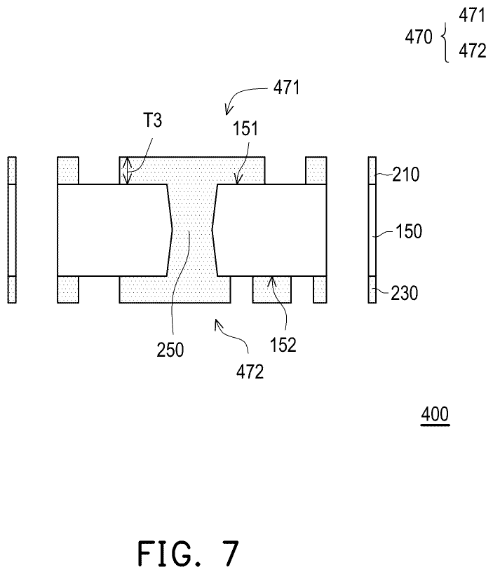

FIG. 1A, FIG. 2A, FIG. 3A, FIG. 4, FIG. 5A, and FIG. 6A are partial perspective views of a manufacturing method of a circuit board according to an embodiment of the present disclosure. FIG. 1B, FIG. 2B, FIG. 3B, FIG. 5B, FIG. 6B, and FIG. 7 are partial cross-sectional schematic views of a manufacturing method of a circuit board according to an embodiment of the present disclosure. For example, FIG. 1A and FIG. 1B may correspond to the same or similar steps, FIG. 2A and FIG. 2B may correspond to the same or similar steps, FIG. 3A and FIG. 3B may correspond to the same or similar steps, FIG. 5A and FIG. 5B may correspond to the same or similar steps, and FIG. 6A and FIG. 6B may correspond to the same or similar steps.

Please refer to FIG. 1A and FIG. 1B, a base 100 is provided. The base 100 may include a core layer 150 and at least one conductive layer located on the core layer 150. For example, the base 100 may include a core layer 150, a first conductive layer 110, and a second conductive layer 120. The first conductive layer 110 is located on the upper surface 151 of the core layer 150. The second conductive layer 120 is located on the lower surface 153 of the core layer 150 (see lower part in the figure). That is to say, the core layer 150 is located between the first conductive layer 110 and the second conductive layer 120.

In an embodiment, the core layer 150 is made of an insulator. Inorganic insulators may include, but are not limited to, glass or ceramics. Organic insulators may include, but are not limited to, polyimide (PI), polycarbonate (PC), polyamide (PA), polyethylene terephthalate (PET), polyethylene naphthalate (PEN), polyethylenimine (PEI), polyurethane (PU), polydimethylsiloxane (PDMS), polymethylmethacrylate (PMMA), polyethersulfone (PES), polyetheretherketone (PEEK), polyolefin, epoxy or other suitable polymers. The insulator may also be a mixture or combination of inorganic and organic substances, for example, a high molecular polymer mixed with glass fiber.

In an embodiment, the first conductive layer 110 and/or the second conductive layer 120 may be formed by sputtering, evaporation or other suitable methods. The material of the first conductive layer 110 and/or the second conductive layer 120 may include copper, but the disclosure is not limited thereto. In an embodiment, the first conductive layer 110 and/or the second conductive layer 120 may be called a seed layer.

In an embodiment, the base 100 may be referred to as composite copper foil, but the present disclosure is not limited thereto.

Referring to FIG. 1A/FIG. 1B to FIG. 2A/FIG. 2B, at least one positioning through-hole 260 and at least one conductive through-hole 259 are formed on the base 100. In addition, for the sake of simplicity, the base 100 having the positioning through-hole 260 and the conductive through-hole 259 is still denoted by the same symbols in the drawings. Moreover, for the sake of simplicity, not all conductive through holes 259 are marked one by one in FIG. 2A.

It is worth noting that the present disclosure does not limit the formation order of the positioning through-hole 260 and the conductive through-hole 259. For example, the positioning through-hole 260 may be formed first; then, the conductive through-hole 259 may be formed later. In another example, the conductive through-hole 259 may be formed first; then, the positioning through-hole 260 may be formed afterwards. In still another example, if the number of positioning through-holes 260 or conductive through-holes 259 is multiple, the plurality of positioning through-holes 260 and conductive through-holes 259 may be formed in an alternating sequence.

In an embodiment, the positioning through-hole 260 may be formed by punching, drilling or other suitable methods. In an embodiment, the conductive through-holes 259 may be formed by laser drilling or other suitable methods.

In an embodiment, the dimension (e.g., aperture) 260D of the positioning through-hole 260 is larger than the dimension (e.g., aperture) 259D of the conductive through-hole 259. In an embodiment, the dimension 260D of the positioning through-hole 260 is approximately 10 times to 500 times the dimension 259D of the conductive through-hole 259. In an embodiment, the dimension 259D of the conductive through-hole 259 may be on the level of micrometer (μm), for example, 2 microns to 500 microns. In an embodiment, the dimension 260D of the positioning through-hole 260 may be on the level of millimeters (mm), such as 1 mm to 5 mm.

Referring to FIG. 2A/FIG. 2B to FIG. 3A/FIG. 3B, the substrate 200 may be formed by forming an additional conductive layer on the base 100 by electroplating or other suitable methods. For example, the third conductive layer 130 may be formed on the first conductive layer 110, and/or the fourth conductive layer 140 may be formed on the second conductive layer 120 (see lower part in the figure). The third conductive layer 130 and/or the fourth conductive layer 140 may be filled with conductive through-hole 259 (marked in FIG. 2A/FIG. 2B), so that the conductive layers on opposite sides of the core layer 150 may be physically and/or electrically connected to each other. For simplicity of description, the conductive layer (i.e., including the first conductive layer 110 and part of the third conductive layer 130) on the upper surface 151 of the core layer 150 may be referred to as the upper conductive layer 210, and the conductive layer (i.e., including the second conductive layer 120 and part of the fourth conductive layer 140) on the lower surface 153 (see lower part in the figure) of the core layer 150 may be referred to as the lower conductive layer 230, and the part of the conductive layer filled in the conductive through-hole 259 (marked in FIG. 2A/FIG. 2B) may be referred to as the conductive via 250 (marked in FIG. 3B). That is, the substrate 200 may include an upper conductive layer 210, a lower conductive layer 230, a core layer 150, and a conductive via 250. The core layer 150 is located between the upper conductive layer 210 and the lower conductive layer 230, and the conductive via 250 penetrates the core layer 150 to connect the upper conductive layer 210 and the lower conductive layer 230.

In an embodiment, since the dimension 260D of the positioning through-hole 260 is larger than (even much larger, i.e., more than 50 times larger than) the dimension 259D of the conductive through-hole 259, the additionally formed conductive layer (such as the third conductive layer 130 and/or the fourth conductive layer 140) substantially does not form a corresponding conductive path in the positioning through-hole 260. That is to say, even though the additionally formed conductive layer (such as the third conductive layer 130 and/or the fourth conductive layer 140) may slightly fill the positioning through-hole 260, the little conductive material filling the positioning through-hole 260 is basically still not enough to form a conductive path that connects the conductive layers on opposite sides of the core layer 150 to each other.

Please refer to FIG. 4, FIG. 5A/FIG. 5B and FIG. 6A/FIG. 6B. The conductive layer of the substrate 200 (marked in FIG. 4) is imprint-etched by the jig 900. The jig 900 has a corresponding convex portion 971 to form the intermediate 300 (marked in FIG. 6A and FIG. 6B) having the concave and convex pattern 370.

In an embodiment, the jig 900 has a convex portion 971 and a flow channel 973, and at least one opening of the flow channel 973 is located in the convex portion 971. In this way, when performing imprint-etching, the convex portion 971 of the jig 900 may be brought into contact to exert force on the conductive layer, while (that is, there is a timing overlap in the action) making the etchant to flow through the flow channel 973, so that the etchant is brought into contact with the opening to at least etch part of the conductive layer corresponding to the convex portion 971, thus forming a corresponding concave portion 371 on the conductive layer. Compared to the method of imprinting without concurrent etching, the imprint-etching method may potentially reduce the occurrence of imprinting defects (such as imprint wrinkles or imprint cracks) and/or burrs (such as metal burrs), thereby potentially enhancing process quality. In contrast to the method of etching without concurrent imprinting (e.g., etching through patterned dry film, patterned photoresist, or other similar patterned masks), the imprint-etching method may potentially offer lower production costs and/or improved production speed or efficiency.

In an embodiment, if necessary, imprint-etching may be performed simultaneously on the conductive layers (i.e., the upper conductive layer 210 and the lower conductive layer 230) on opposite sides of the core layer 150. For example, the jig 900 includes an upper jig 910 and a lower jig 930. When the jig 900 is utilized to perform imprint-etching on the conductive layer of the substrate 200, the substrate 200 is clamped between the upper jig 910 and the lower jig. 930, so that the upper jig 910 performs imprint-etching on the upper conductive layer 210, while (that is, there is a timing overlap in the action) the lower jig 930 performs imprint-etching on the lower conductive layer 230. In this way, the production speed or efficiency may be further improved.

In an embodiment, the hardness of the jig 900 is greater than the hardness of the conductive layer. In this way, the utilization frequency of the jig 900 may be increased. In an embodiment, when the jig 900 is utilized to perform imprint-etching on the conductive layer of the substrate 200, part of the conductive layer may extend due to being squeezed by the convex portion 971 of the jig 900. That is to say, for the intermediate 300 having the concave and convex pattern 370, the thickness T2 of the convex portion 372 of the concave and convex pattern 370 may be greater than or equal to the thickness T1 (marked in FIG. 3B) of the conductive layer before imprint-etching.

In an embodiment, the hardness of the jig 900 is greater than the hardness of the conductive layer, and the etching rate of the etchant on the conductive layer is higher than the etching rate of the etchant on the jig 900. For example, the main component of the conductive layer is copper, the etchant may include copper Cu etchant, and the material of the jig 900 may include, for example, stainless steel, ceramics or hard polymer materials (such as bakelite).

In an embodiment, when performing imprint-etching, the etchant may permeate into the space between the jig 900 (such as the convex portion 971 of the jig 900) and the corresponding conductive layer, but the disclosure is not limited thereto. The aforementioned permeation may be caused by capillary phenomena or corresponding etchings in the conductive layer.

In an embodiment, the design of the jig 900 and/or the corresponding pattern basically prevents the convex portion 971 of the jig 900 from overlapping the conductive via 250.

In an embodiment, at least one of the upper jig 910 and the lower jig 930 has a positioning pin 960, and when the substrate 200 is clamped between the upper jig 910 and the lower jig 930, the positioning pin 960 passes through the positioning through-hole 260. In this way, prior to or during the process of imprint-etching (for example, during the process of clamping the substrate 200 between the upper jig 910 and the lower jig 930), it is possible to reduce the possibility of the substrate 200 being shifted, so that the substrate 200 and the jig 900 are precisely positioned relative to each other.

In an embodiment, the positioning through-hole 260 corresponds to the corner CR of the substrate 200, and the concave portion 371 of the concave and convex pattern 370 of the intermediate 300 is substantially located within the maximum closed contour formed by all positioning through-holes 260. In this way, prior to or during the process of imprint-etching (for example, during the process of clamping the substrate 200 between the upper jig 910 and the lower jig 930), the substrate 200 may be well stretched and/or fixed by the positioning pin 960 inserted into the positioning through-hole 260, so as to reduce the possibility of creases and/or deviation of the substrate 200, thereby improving process quality.

As shown in FIG. 6A/FIG. 6B, after the imprint-etching is completed, the jig 900 may be separated from the intermediate 300. In addition, for simplicity, the upper jig 910 and the lower jig 930 that are separated after the imprint-etching is completed are not shown in FIG. 6B.

It is worth noting that, as shown in FIG. 6B, after the imprint-etching is completed, there may still be some residual conductive layer in the concave portion 371 of the concave and convex pattern 370 of the intermediate 300. That is to say, the thickness of the concave portion 371 of the concave and convex pattern 370 may be greater than 0, for example, less than or approximately equal to 0.1 micron. In an embodiment not shown, the concave portion 371 of the concave and convex pattern 370 of the intermediate 300 may expose part of the surface of the core layer 150.

Referring to FIG. 6B to FIG. 7, the corresponding portion of the conductive layer remaining in the concave portion 371 of the concave and convex pattern 370 of the intermediate 300 may be removed by etching or other appropriate methods to form a circuit board 400 with a circuit pattern 470. The wiring of the circuit board 400 (i.e., the distribution of the circuit pattern 470) basically corresponds to the convex portion 372 of the concave and convex pattern 370 of the intermediate 300, and the difference is that the thickness is smaller. That is to say, the thickness T3 of the circuit pattern 470 is less than the thickness T2 of the convex portion 372 of the concave and convex pattern 370 of the intermediate 300. A part of the circuit pattern 470 (i.e., a part of the upper conductive layer 210) located on the upper surface 151 of the core layer 150 may be referred to as an upper circuit layer 471, and a part of the circuit pattern 470 (i.e., a part of the lower conductive layer 230) located on the lower surface 153 (see lower part in the figure) of the core layer 150 may be referred to as the lower circuit layer 472, and the corresponding circuits in the upper circuit layer 471 and the corresponding circuits in the lower circuit layer 472 may be electrically connected through corresponding conductive via 250.

In an embodiment, the width of the circuit in the upper circuit layer 471 or the width of the circuit in the lower circuit layer 472 may be less than or approximately equal to 100 microns, for example, 50 microns, 25 microns or 18 microns, but the present disclosure is not limited thereto.

In an embodiment, the minimum spacing between two adjacent circuits in the upper circuit layer 471 or the minimum spacing between two adjacent circuits in the lower circuit layer 472 may be less than or approximately equal to 100 microns, for example, 50 microns, 25 microns or 18 micron, but the disclosure is not limited thereto.

In summary, through the exemplary method of the present disclosure, circuit boards may be manufactured efficiently. Moreover, in the exemplary method of manufacturing the circuit board according to the present disclosure, the lithography process may be omitted, thereby resulting in a simpler process and potentially lower manufacturing costs.

What is claimed is:

1. A manufacturing method of a circuit board, comprising:
providing a substrate with a conductive layer;
using a jig to imprint-etch the conductive layer of the substrate to form an intermediate with a concave and convex pattern; and
etching the intermediate to form a circuit board with a circuit pattern, wherein the circuit pattern corresponds to a convex portion of the concave and convex pattern.

2. The manufacturing method of the circuit board according to claim 1, wherein the jig has a convex portion and a flow channel, and wherein:
at least one opening of the flow channel is located at the convex portion; and
a concave portion of the concave and convex pattern corresponds to the convex portion of the jig.

3. The manufacturing method of the circuit board according to claim 2, wherein the step of using the jig to imprint-etch the conductive layer of the substrate comprises flowing an etchant through the flow channel, so that the etchant contacts the opening to etch a part of the conductive layer.

4. The manufacturing method of the circuit board according to claim 2, wherein the conductive layer comprises an upper conductive layer and a lower conductive layer, and the substrate comprises:
the upper conductive layer;
the lower conductive layer;
a core layer located between the upper conductive layer and the lower conductive layer; and
a conductive via penetrating the core layer to connect the upper conductive layer and the lower conductive layer, wherein:
when the jig is used to imprint-etch the conductive layer of the substrate, the convex portion of the jig does not overlap with the conductive via.

5. The manufacturing method of the circuit board according to claim 1, wherein the jig comprises an upper jig and a lower jig, and when the jig is used to imprint-etch the conductive layer of the substrate, the substrate is clamped between the upper jig and the lower jig.

6. The manufacturing method of the circuit board according to claim 5, wherein:
the substrate has a positioning through-hole;
at least one of the upper jig and the lower jig has a positioning pin; and
when the substrate is clamped between the upper jig and the lower jig, the positioning pin penetrates the positioning through-hole.

7. The manufacturing method of the circuit board according to claim 6, wherein the positioning through-hole corresponds to a corner of the substrate.

8. The manufacturing method of the circuit board according to claim 1, wherein a hardness of the jig is greater than a hardness of the conductive layer.

9. The manufacturing method of the circuit board according to claim 1, wherein a thickness of the convex portion of the concave and convex pattern is greater than or equal to a thickness of the conductive layer.

10. The manufacturing method of the circuit board according to claim 1, not comprising a lithography process.
